(19) United States
(12) Patent Application Publication
(10) Pub. No.: US 2015/0019795 A1
(43) Pub. Date: Jan. 15, 2015

(54) MEMORY SYSTEM FOR SHADOWING VOLATILE DATA

(71) Applicant: LSI Corporation, San Jose, CA (US)

(72) Inventors: Justin R. McCollum, Lawrenceville, GA (US); Jason M. Stuhlsatz, Dacula, GA (US); Moby J. Abraham, Lilburn, GA (US)

(73) Assignee: LSI Corporation, San Jose, CA (US)

(21) Appl. No.: 14/043,190

(22) Filed: Oct. 1, 2013

Related U.S. Application Data
(60) Provisional application No. 61/845,495, filed on Jul. 12, 2013.

(51) Int. Cl. G11C 14/00; G06F 12/02

(52) U.S. Cl. CPC G11C 14/0018; G06F 12/0246
USPC 711/103

(57) ABSTRACT

An apparatus configured to shadow volatile data while minimizing read latency is described. In an implementation, the apparatus includes a memory controller configured to operatively couple to a volatile memory device and a non-volatile memory device. The volatile memory device includes a volatile memory cell and the non-volatile memory device includes a corresponding non-volatile memory cell. The volatile memory device has a first transfer speed and the non-volatile memory device has a second transfer speed. The memory controller is configured to cause storage of data to the volatile memory cell and the non-volatile memory cell and to determine an occurrence of an unanticipated power outage. The memory controller is configured set a read speed to the second transfer speed and to cause replication of the data from the non-volatile memory cell to a corresponding volatile memory cell upon recovery from the unanticipated power outage.

### CROSS-REFERENCE TO RELATED APPLICATIONS

The present application claims the benefit under 35 U.S.C. §119(e) of U.S. Provisional Application Ser. No. 61/845,495, entitled MEMORY SYSTEM CONFIGURED TO PRESERVE DATA OVER ONE OR MORE POWER CYCLES, filed on Jul. 12, 2013. U.S. Provisional Application Ser. No. 61/845,495 is herein incorporated by reference in its entirety.

### FIELD OF THE INVENTION

The present invention is directed to a memory system, and more particularly to a memory system configured to shadow volatile data while minimizing read latency.

### BACKGROUND

Computing devices, such as personal computers, servers, mobile computing devices, networking devices, and so forth, include computer storage devices for retaining and providing digital data. Computer storage devices range from volatile storage devices, which do not retain data when the device is powered down, to non-volatile storage devices, which retain data when the device is powered down. Volatile storage devices can include random-access memory devices, such as dynamic random-access memory (DRAM), which are utilized due to the devices' low-latency characteristics, and non-volatile storage devices can include non-volatile random-access memory (NVRAM). These types of storage devices are utilized for long-term persistent storage.

### SUMMARY

An apparatus is described that is configured to shadow volatile data while minimizing read latency. In an implementation, the apparatus includes a memory controller configured to operatively couple to a volatile memory device and a non-volatile memory device. The volatile memory device includes a volatile memory cell and the non-volatile memory device includes a corresponding non-volatile memory cell. The volatile memory device has a first transfer speed and the non-volatile memory device has a second transfer speed, which is different from the first transfer speed. The memory controller is configured to cause storage of data to the volatile memory cell and the non-volatile memory cell and to determine an occurrence of an unanticipated power outage. The memory controller is configured set a read speed to the second transfer speed and to cause replication of the data from the non-volatile memory cell to a corresponding volatile memory cell upon recovery from the unanticipated power outage.

This Summary is provided to introduce a selection of concepts in a simplified form that are further described below in the Written Description. This Summary is not intended to identify key features or essential features of the claimed subject matter, nor is it intended to be used as an aid in determining the scope of the claimed subject matter.

### BRIEF DESCRIPTION OF THE FIGURES

The Written Description is described with reference to the accompanying figures. The use of the same reference numbers in different instances in the description and the figures may indicate similar or identical items.

FIG. 1 is a block diagram of a memory system configured to preserve data in accordance with an example implementation of the present disclosure.

FIG. 2 is a block diagram illustrating a portion of memory controller, a volatile memory device, and a non-volatile memory device of the memory system shown in FIG. 1 in accordance with an example implementation of the present disclosure.

FIG. 3 is a method diagram for preserving data within a memory system, such as the memory system illustrated in FIG. 1, in accordance with the present disclosure.

### WRITTEN DESCRIPTION

Batteries and capacitors are utilized by volatile memory devices to store and to preserve the memory contents (e.g., data) over multiple power cycles. However, batteries and capacitors have durability limitations, such as in high temperature server environments. Non-volatile memory devices are utilized to store memory contents over multiple power cycles. However, non-volatile memory devices may be limited in size and access, or transfer (e.g., latency), speed. For example, a read cycle of a non-volatile memory device is typically longer than a read cycle of a volatile memory device. These limitations may make it impractical to utilize non-volatile memory devices as the main memory for redundant array of independent disk (RAID) systems.

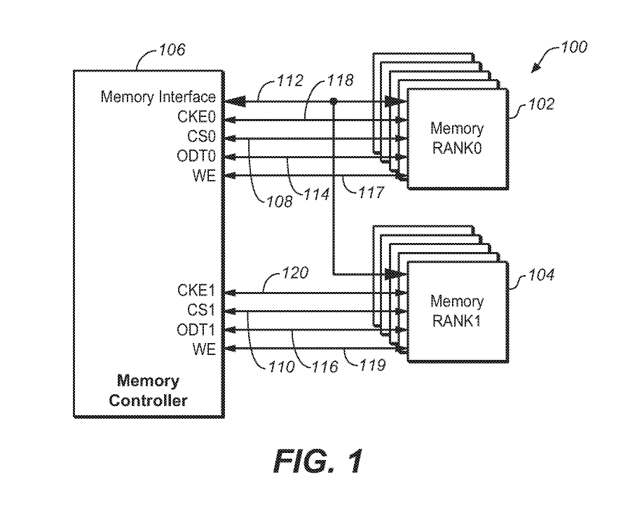

FIG. 1 is a block diagram illustrating a memory system 100, such as a RAID system, configured to shadow data volatile data while minimizing read latency (e.g., shadowing data in a volatile memory (e.g., DDR DRAM) cell to a non-volatile memory cell (e.g., non-volatile DRAM)) in accordance with an example embodiment of the present disclosure. As shown, the memory system 100 includes memory device 102, 104. Each of the memory device 102, 104 includes a plurality of memory cells configured to store data. In a specific embodiment of the present disclosure, the memory device 102 comprises a volatile memory device (i.e., a DRAM memory device, etc.), and the memory device 104 may comprises a non-volatile memory device. In some embodiments of the present disclosure, the memory device 102 comprises double data rate (DDR) DRAM, and the memory device 104 comprises non-volatile random-access memory (NVRAM). The NVRAM devices may include, but is not limited to: magnetoresistive random-access memory (MRAM), parameter random access memory (PRAM), resistive random-access memory (ReRAM), Ferroelectric random access-memory, Carbon-Nanotube random-access memory, or the like. As shown, the memory device 102, 104 are communicatively connected to a memory controller 106 by way of one or more data buses. In some implementations, only one data bus is utilized, and in other implementations a plurality of data buses is utilized. The memory controller 106 is configured to communicatively interface with each memory device 102, 104 to control reading and writing of data from/to the memory device 102, 104. In an embodiment of the present disclosure, the memory controller 106 is configured to receive requests (i.e., commands) to read data from the memory device 102 or to write data to the memory device 102, 104. When addressing each memory device 102, 104, the memory controller 106 is configured to differentiate each memory device 102, 104 by a rank. For example, as illustrated in FIG. 1, the memory device 102 may be assigned rank 0 and the memory device 104 may be assigned rank 1. In an implementation of the present disclosure, each rank is controlled by a dedicated control signal (e.g., each memory device 102, 104 is controlled by a separate control protocol). Any number of ranks and memory device may be used and each memory device may be used in any position in accordance with the present disclosure. Additionally, while only one rank 0 memory device 102 and rank 1 memory device 104 is shown in FIG. 1, it is understood that there may be multiple rank 0 memory devices and multiple rank 1 memory devices in accordance with the present disclosure.

As shown in FIG. 1, the memory controller 106 is configured to issue chip select signals CS0 and CS1 over a respective communication interface 108, 110. The communication interface 108 is communicatively connected to the memory device 102, and the communication interface 110 is communicatively connected to the memory device 104. An active CS0 signal may cause the memory device 102 to receive address and/or data signals from the memory interface 112, and an active CS1 signal may cause the memory device 104 to receive address and/or data signals from the memory interface 112. Thus, the controller 106 is configured to issue address and/or data signals over the interface 112. As shown, the memory interface 112 is common to both the memory device 102 and the memory device 104. Accordingly, the memory controller 106 is configured to furnish the signal CS0 to indicate a memory operation for the memory device 102 while the memory controller 106 is configured to provide the signal CS1 to indicate a memory operation for the memory device 104. In some implementations of the present disclosure, the memory controller may be implemented externally to the system 100. In other implementations, the CS differentiation control logic is external to the system 100.

The memory controller 106 is also configured to furnish an on-die termination signal ODT0, ODT1 to the memory device 102, 104, respectively. As shown, the on-die termination signal ODT0 is provided to the memory device 102 via the communication interface 114, and the on-die termination signal ODT1 is provided to the memory device 102 via the communication interface 116. The on-die termination signals are configured to reduce noise and/or signal reflections of signals received by the respective memory device 102, 104 by furnishing a termination impedance. The memory controller 106 is also configured to issue a clock enable signal CKE0, CKE1 via communication interfaces 118, 120, respectively. For example, the clock enable signal CKE0 is issued to the memory device 102, and the clock enable signal CKE1 is issued to the memory device 104. In an embodiment of the present disclosure, a respective memory device 102, 104 is configured to activate in response to receiving a respective clock enable signal CKE0, CKE1. Accordingly, the memory controller 106 is configured to furnish a clock signal CKE0, CKE1 to activate a corresponding memory device 102, 104 as well as a chip select signal CS0, CS1 to indicate an operation for the respective memory device 102, 104. The memory controller 106 is configured to select between a read operation or a write operation utilizing write enable signals WE0, WE1, which are issued to the memory devices 102, 104 via the communication interfaces 117, 119, respectively. For example, a logic high write enable signal may represent a write operation and a logic low write enable signal may represent a read operation, or vice versa.

As described above, the memory devices 102, 104 are configured to receive individual clock enable signals from a memory controller 106. Thus, the memory device 102 receives the clock enable signal CKE0, and the memory device 104 receives the clock enable signal CKE1. Because each memory device 102, 104 receives its own clock enable signal, each memory device 102, 104 may be independently controlled by a respective chip select CS0, CS1, clock enable signals CKE0, CKE1, and write enable signals WE0, WE1.

Accordingly, the memory controller 106 is configured to provide command and address signals to the memory interface bus 112 that is coupled to multiple memory devices. The memory controller 106 can independently control individual memory device within the system 100 by providing a respective chip select signal for each of the memory devices and a respective clock enable signal for each of the memory devices. In another implementation of the present disclosure, the system 100 may include external control logic to the memory controller 106 that drives the control signals to the memory devices 102, 104 based upon whether the transfer is a read operation or a write operation to the corresponding memory device 102, 104.

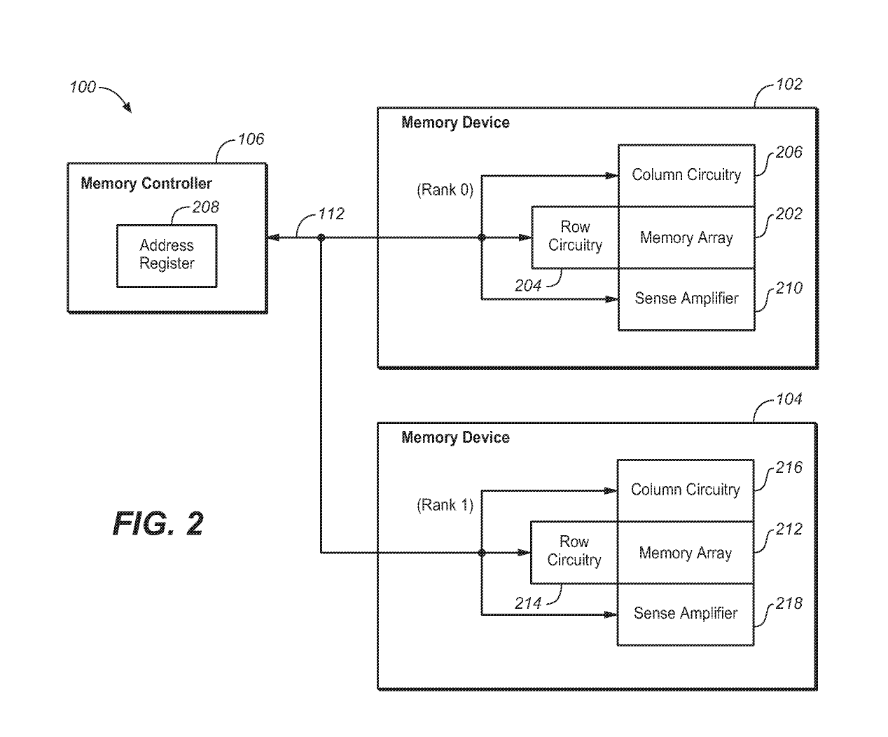

FIG. 2 illustrates an example embodiment of the memory device 102 and the memory device 104 in accordance with the present disclosure. As shown, the memory device 102 comprises an array 202 of volatile memory cells arranged in rows and columns. The memory device 102 also includes row decode circuitry 204 and column decode circuitry 206 are provided to decode address signals provided to the memory array 202. Address signals are received from the interface 112 and decoded to access the memory array 202 (e.g., access one or more blocks of memory cells). The memory controller 106 is configured to manage input of commands, addresses, and data to the memory device 102, as well as output of data from the memory device 102. For example, the memory controller 106 includes an address register 208 that is communicatively connected to the row decode circuitry 204 and the column decode circuitry 206 to latch the address signals prior to decoding. The memory device 102 also includes a sense amplifier 210 that is configured to sense logic levels from at least one bitline that represent the data (i.e., logic 0 or logic 1) stored in the memory cell during a read operation. The sense amplifier 210 is further configured to amplify the sensed signal (e.g., a voltage swing) to recognizable logic levels.

During a write operation, target memory cells of the memory array 202 are charged or discharged to a desired value (i.e., a logic 0 or a logic 1). In an embodiment, the write operation can be accomplished by charging (e.g., opening) a respective wordline. Once the wordline is open, a respective bitline's sense amplifier is temporarily forced to a desired high or low voltage state to cause the bitline to charge or discharge the memory cell capacitor to the desired value.

As shown in FIG. 2, the memory device 104 comprises an array 212 of non-volatile memory cells arranged in rows and columns. The memory device 104 also includes row decode circuitry 214 and column decode circuitry 216 to decode address signals provided to the memory array 212. Address signals are received and decoded to access the memory array 212 (e.g., access one or more blocks of memory cells). The memory controller 106 is configured to manage input of commands, addresses, and data to the memory device 104, as well as output of data from the memory device 104. The address register 208 is also communicatively connected to the row decode circuitry 214 and the column decode circuitry 216 to latch the address signals prior to decoding.

The memory device 104 also includes a sense amplifier 218 that is configured to sense logic levels from at least one bitline that represent the data (i.e., logic 0 or logic 1) stored in the memory cell during a read operation. The sense amplifier 218 is further configured to amplify the sensed signal (e.g., a voltage swing) to recognizable logic levels. During a write operation, target memory cells of the memory array 212 are charged or discharged to a desired value (i.e., a logic 0 or a logic 1). In an embodiment, the write operation can be accomplished by charging (e.g., opening) a respective wordline. Once the wordline is open, a respective bitline's sense amplifier is temporarily forced to a desired high or low voltage state to cause the bitline to charge or discharge the memory cell capacitor to the desired value.

As described above, the memory controller 106 is configured to issue commands to the memory device 102 and the memory device 104 based upon a rank of the respective die 102, 104. The commands may be issued from the memory controller 106 in response to receiving a command, or instruction, from a host system that implements the system 100. The system 100 is configured to preserve data across power cycles. Thus, the system 100 is configured to shadow volatile data stored in a portion of a volatile memory cell 102 to a corresponding portion of a non-volatile memory cell 104 to preserve the data in the event of an unanticipated power loss (e.g., an event that would force the memory controller 106 to reboot before the memory cell 106 could cause volatile data to be transferred to non-volatile memory).

During a write operation, the memory controller 106 is configured to issue a write command to the volatile memory device 102 and the non-volatile memory device 104. In some embodiments of the present disclosure, the write command comprises a furnishing the address data (e.g., wordline and bitline) to the memory device 102 and the memory device 104, the data to be stored within the memory device 102 and the memory device 104, as well as issuing a chip select signal CS0, CS1 to both memory device 102, 104. Accordingly, the data to be stored in the volatile memory device 102 is also stored in the memory device 104. The data is stored in the memory device 104 utilizing at least substantially the same addressing protocol as the memory device 102. Thus, during a write operation, the memory device 106 issues the write command concurrently, or at least substantially concurrently, to the memory device 102 and the memory device 104. In some embodiments of the present disclosure, the non-volatile memory device 104 is smaller (i.e., has smaller storage capacity) as compared to volatile memory device 102 and the data to be stored comprises pre-identified data, such as user data. Thus, the memory controller 106 is configured to identify that the data is user data and to cause the user data to be stored within both the memory device 102 and the memory device 104. For example, the memory controller 106 is configured to determine a portion of the data as data to be stored redundantly (e.g., user data) within the system 100. Based upon this determination, the memory controller 106 issues a write command (e.g., address data, data to be stored, write enable signals to the devices 102, 104, chip select signals to the devices 102, 104, etc.) to the memory device 102 and the memory device 104. Based upon the write command, the data identified (determined) to be stored redundantly is stored within the memory device 102 and the memory device 104 as described in greater detail herein. The memory controller 106 is configured to determine whether an unanticipated power outage occurred. An unanticipated power outage may be defined as a power outage occurred outside a normal power down protocol.

During a read operation, the memory controller 106 is configured to issue a chip select signal CS0 for the memory device 102 (e.g., the rank 0 memory device). Thus, the memory controller 106 is configured to issue write instructions to both the memory device 102 and the memory device 104 such that data is written to corresponding memory cells within each device 102, 104. In an implementation of the present disclosure, during a read operation, the memory controller 106 is configured to issue read instructions to the memory device 102 (i.e., the memory controller 106 does not issue read instructions to the memory device 104).

When the memory controller 106 detects an unanticipated power outage has occurred (i.e., the controller 106 powers up and determines that the system 100 has recovered from an unanticipated power outage), the memory controller 106 is configured to logically separate the memory device 102 and the memory device 104 (i.e., the memory controller 106 treats the devices 102, 104 two discrete memory devices) during a read operation. The memory controller 106 is configured to logically group the memory device 102 and the memory device 104 together (e.g., the memory controller 106 treats the devices 102, 104 as a single memory device) during a write operation. For example, the controller 106 is configured to logically group the memory device 102 and the memory device 104 when the memory control 106 determines that the data is to be stored redundantly (e.g., the data is user data). In an implementation of the present disclosure, the transfer speeds (e.g., speed to write/read to/from a memory device) may vary due to the architectures (e.g., volatile/non-volatile architectures) of the memory device 102 and the memory device 104. For example, the memory device 102 may have a faster transfer speed as compared to the transfer speed of the memory device 104. Thus, the read speed of the memory device 102 may differ as compared to the read speed of the memory device 104. Once the memory controller 106 determines that an unanticipated power outage has occurred, the memory controller 106 is configured to set the read speed to the read speed of the memory device 104 (i.e., set the read speed to the rank 1 memory device). Once the read speed has been set, the controller 106 is configured to copy (i.e., replicate) the data from the memory device 104 to the memory device 102. For example, the controller 106 is configured to issue a read command (i.e., address data, proper CS1 signal, proper WE1 signal) to the array 202 such that at least substantially all of the data stored within the memory device 104 is copied to the array 212. Thus, the data stored in a first memory cell 310 is transferred for storage purposes to a corresponding first memory cell 338, and so forth. The controller 106 is configured to set the read speed of the system 100 to the read speed of the memory device 102 once the contents stored in the memory device 104 are transferred to the memory device 102.

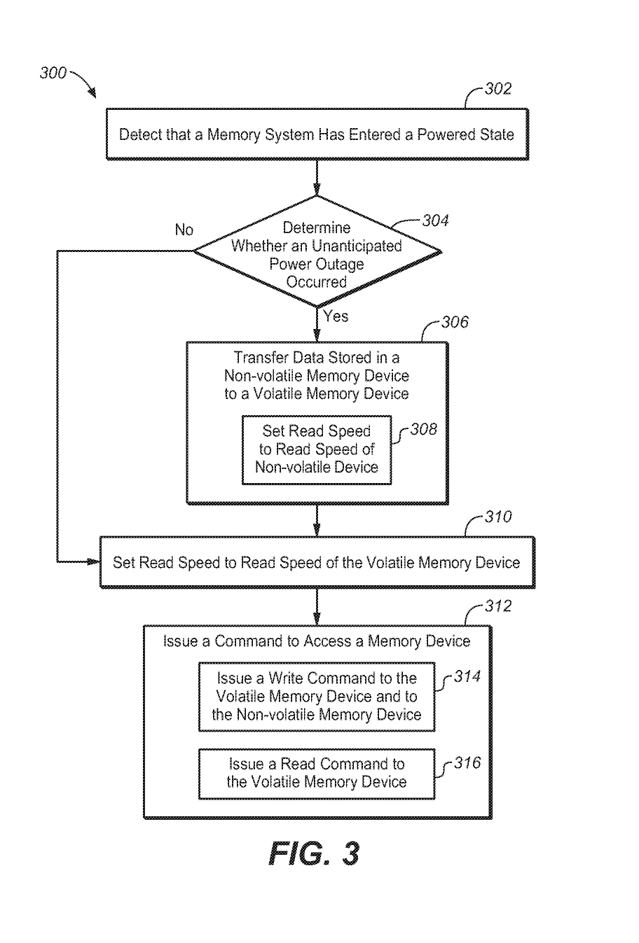

FIG. 3 depicts an example method 300 in accordance with an example embodiment of the present disclosure. A detection is made that a memory system has entered a powered state (Block 302). The controller 106 is configured to detect that the memory system 100 has entered a powered state (i.e., the memory system has powered on). For example, the controller 106 receives a signal indicating that the memory system 100 has entered a powered state. A determination is made of whether an unanticipated power outage occurred (Decision Block 304). Once the memory controller 106 has detected that the system 100 has entered a powered state, the memory controller 106 is configured to determine whether the memory system 100 has recovered from an unanticipated power outage. The controller 106 may determine that the power outage is an unanticipated power outage due to controller 106 entering a power down state outside of a predetermined power down protocol. If the power outage is an unanticipated power outage (YES from Decision Block 304), at least a portion of the data stored within the non-volatile memory device is replicated, or copied, to the volatile memory device (Block 306). In an embodiment of the present disclosure, the controller 106 is configured to set a read speed to the read speed of the memory device 104 (e.g., the rank 1 memory device) when the system 100 is recovering from an unanticipated power outage (Block 308). The controller 106 is configured to cause the content stored within the memory device 104 to the memory device 102. The controller 106 is configured to cause transfer of the data to the memory device 102 until at least substantially all of the data stored within the memory device 104 is transferred to the device 102. Thus, the memory controller 106 is configured to issue a read operation to the memory device 104 when the system 100 is recovering from an unanticipated power outage.

If the power outage is not an unanticipated power outage (NO from Decision Block 304) or transfer of the data has completed, the read speed is set to the read speed of the volatile memory device (Block 310). As described above, the controller 106 is configured to set the read speed to the read speed of the memory device 102 (e.g., the rank 0 memory device). In some embodiments of the present disclosure, the controller 106 determines there is no need to copy data from the device 104 to the device 102 since the power down was an anticipated power down. A command to access a memory device is issued (Block 312). In an embodiment of the present disclosure, the memory controller 106 is configured to issue a write command to the memory device 102 and the memory device 104 (Block 314). As described above, the memory controller 106 is configured to logically group the memory device 102 and the memory device 104 together during a write operation. Thus, the memory controller 106 treats the memory device 102 and the memory device 104 as a single memory unit during a write operation. During a write operation, the controller 106 is configured to issue a write command via the interface 112 that includes signals that represent a memory address to store the data and includes signals that represent the data to store. The controller 106 is also configured to enable the chip select signals CS0, CS1 to cause the memory devices 102, 104 to receive (e.g., recognize) the write command.

In another embodiment of the present disclosure, the memory controller 106 is configured to issue a read command to the memory device 102 (Block 316). As described above, the memory controller 106 is configured to logically separate the memory device 102 and the memory device 104 during a read operation. Thus, the memory controller 106 treats the memory device 102 and the memory device 104 as discrete memory units during a read operation. During a read operation, the controller 106 is configured to issue a read command via the interface 112 that includes signals that represent a memory address to read the data from. The controller 106 is also configured to enable the chip select signal CS0 to cause the memory devices 102 to receive (e.g., recognize) the read command.

Generally, any of the functions described herein can be implemented using hardware (e.g., fixed logic circuitry such as integrated circuits), software, firmware, manual processing, or a combination thereof. Thus, the blocks discussed in the above disclosure generally represent hardware (e.g., fixed logic circuitry such as integrated circuits), software, firmware, or a combination thereof. In embodiments of the disclosure that manifest in the form of integrated circuits, the various blocks discussed in the above disclosure can be implemented as integrated circuits along with other functionality. Such integrated circuits can include all of the functions of a given block, system, or circuit, or a portion of the functions of the block, system or circuit. Further, elements of the blocks, systems, or circuits can be implemented across multiple integrated circuits. Such integrated circuits can comprise various integrated circuits including, but not necessarily limited to: a system on a chip (SoC), a monolithic integrated circuit, a flip chip integrated circuit, a multichip module integrated circuit, and/or a mixed signal integrated circuit. In embodiments of the disclosure that manifest in the form of software, the various blocks discussed in the above disclosure represent executable instructions (e.g., program code) that perform specified tasks when executed on a processor. These executable instructions can be stored in one or more tangible computer readable media. In some such embodiments, the entire system, block or circuit can be implemented using its software or firmware equivalent. In some embodiments, one part of a given system, block or circuit can be implemented in software or firmware, while other parts are implemented in hardware.

Although embodiments of the disclosure have been described in language specific to structural features and/or methodological acts, it is to be understood that the subject matter defined in the appended claims is not necessarily limited to the specific embodiments described. Although various configurations are discussed, the apparatus, systems, subsystems, components and so forth can be constructed in a variety of ways without departing from teachings of this disclosure. Rather, the specific features and acts are disclosed as embodiments of implementing the claims.

What is claimed is:

1. An apparatus comprising:
a memory controller configured to operatively couple to a volatile memory device and a non-volatile memory device, the volatile memory device having a first transfer speed and the non-volatile memory device having a second transfer speed, the volatile memory device including at least one volatile memory cell and the non-volatile memory device including at least one non-volatile memory cell, the at least one non-volatile memory cell corresponding to the at least one volatile memory cell,
the memory controller configured to cause storage of data to the at least one volatile memory cell and the at least one non-volatile memory cell; determine an occurrence of an unanticipated power outage; set a read speed to the second transfer speed; and cause replication of the data from the at least one non-volatile memory cell to the at least one volatile memory cell.

2. The apparatus as recited in claim 1, wherein the at least one volatile memory cell comprises a dynamic random access memory (DRAM) cell and the at least one non-volatile memory cell comprises a non-volatile DRAM cell.

3. The apparatus as recited in claim 1, wherein the first transfer speed is different from the second transfer speed.

4. The apparatus as recited in claim 1, wherein the memory controller is configured to logically group the non-volatile memory device and the volatile memory device during a write operation.

5. The apparatus as recited in claim 4, wherein the memory controller is configured to logically separate the non-volatile memory device and the volatile memory device during a read operation.

6. The apparatus as recited in claim 1, wherein the memory controller is configured to issue a write command at least substantially concurrently to the volatile memory device and to the non-volatile memory device.

7. The apparatus as recited in claim 1, wherein the at least one non-volatile memory cell comprises the same write address as the volatile memory cell.

8. A system comprising:
a volatile memory device including an array of volatile memory cells, the array of volatile memory cells configured to store data, the volatile memory device having a first transfer speed;
a non-volatile memory device including an array of non-volatile memory cells, the array of non-volatile memory cells configured to store data, the non-volatile memory device having a second transfer speed;
a memory controller operatively coupled to the volatile memory device and to the non-volatile memory device, the memory controller configured to cause storage of data to at least one volatile memory cell within the array of volatile memory cells and to at least one corresponding non-volatile memory cell within the array of non-volatile memory cells; determine an occurrence of an unanticipated power outage; set a read speed to the second transfer speed; and cause replication of the data from the at least one non-volatile memory cell to the at least one volatile memory cell upon recovery from the unanticipated power outage.

9. The system as recited in claim 8, wherein the at least one volatile memory cell comprises a dynamic random access memory (DRAM) cell and the at least one non-volatile memory cell comprises a non-volatile DRAM cell.

10. The system as recited in claim 9, wherein the first transfer speed is different from the second transfer speed.

11. The system as recited in claim 8, wherein the memory controller is configured to logically group the non-volatile memory device and the volatile memory device together during a write operation.

12. The system as recited in claim 11, wherein the memory controller is configured to logically separate the non-volatile memory device and the volatile memory device during a read operation.

13. The system as recited in claim 8, wherein the memory controller is configured to issue a write command at least substantially concurrently to the volatile memory device and to the non-volatile memory device.

14. The system recited in claim 8, wherein the at least one non-volatile memory cell comprises the same write address as the volatile memory cell.

15. A method comprising:
detecting that a memory controller has entered a powered state, the memory controller operatively coupled to a volatile memory device and to a non-volatile memory device, the volatile memory device having a first transfer speed and the non-volatile memory device having a second transfer speed;
determining whether the memory controller has recovered from an unanticipated power outage, the volatile memory device including at least one volatile memory cell and the non-volatile memory device including at least one non-volatile memory cell, the at least one non-volatile memory cell corresponding to the at least one volatile memory cell;
setting a read speed to the second transfer speed when the memory controller has recovered from the unanticipated power outage; and
causing replication of data stored within the at least one non-volatile memory cell to the at least one volatile memory cell.

16. The method as recited in claim 15, wherein the at least one volatile memory cell comprises a dynamic random access memory (DRAM) cell and the at least one non-volatile memory cell comprises a non-volatile DRAM cell.

17. The method as recited in claim 15, wherein the first transfer speed is different from the second transfer speed.

18. The method as recited in claim 15, further comprising logically grouping the non-volatile memory device and the volatile memory device during a write operation.

19. The method as recited in claim 18, further comprising logically separating the non-volatile memory device and the volatile memory device during a read operation.

20. The method as recited in claim 15, further comprising issuing a write command at least substantially concurrently to the volatile memory device and to the non-volatile memory device.
